(19) United States
(12) Patent Application Publication
(10) Pub. No.: US 2012/0003842 A1
(43) Pub. Date: Jan. 5, 2012

(54) METHOD FOR FORMING SILICON OXIDE FILM AND METHOD FOR MANUFACTURING SEMICONDUCTOR DEVICE

(75) Inventors: Hirokazu Ueda, Hyogo (JP); Yusuke Ohsawa, Hyogo (JP); Yoshinobu Tanaka, Hyogo (JP)

(73) Assignee: TOKYO ELECTRON LIMITED, Minato-ku, Tokyo (JP)

(21) Appl. No.: 13/202,108

(22) PCT Filed: Dec. 10, 2009
(86) PCT No.: PCT/JP2009/070691

§ 371 Date: Sep. 27, 2011

(30) Foreign Application Priority Data
Feb. 19, 2009 (JP) 2009-036750

(51) Int. Cl. H01L 21/316; C23C 16/56; C23C 16/46; C23C 16/511; C23C 16/40; C23C 16/455

(52) U.S. Cl. 438/788; 427/535; 257/E21.278

(57) ABSTRACT

There is provided a silicon oxide film forming method including forming a silicon oxide film on a processing target substrate W by supplying a silicon compound gas, an oxidizing gas and a rare gas into a processing chamber 32 while maintaining a surface temperature of a holding table 34 capable of holding thereon the processing target substrate W at a temperature equal to or lower than about 300° C. and by generating microwave plasma within the processing chamber 32, and performing a plasma process on the silicon oxide film formed on the processing target substrate W by supplying an oxidizing gas and a rare gas into the processing chamber 32 and by generating microwave plasma within the processing chamber 32.

### TECHNICAL FIELD

The present invention relates to a method for forming a silicon oxide film and a method for manufacturing a semiconductor device; and, more particularly, to a method for forming a silicon oxide film on a conductive layer of a semiconductor device and a method for manufacturing the semiconductor device including the silicon oxide film.

### BACKGROUND ART

In a conventional semiconductor device such as a MOS (Metal Oxide Semiconductor) transistor, in order to form an insulating layer such as a gate oxide film having high insulation property (i.e., high resistance or high leakage property), a silicon oxide film serving as the insulating layer is formed by a thermal oxidation method. Specifically, a silicon substrate used as a processing target substrate is heated to, e.g., about 700° C. and, in this state, the silicon oxide film is formed by a high-temperature thermal CVD (Chemical Vapor Deposition).

A method for forming a silicon oxide film by such a thermal oxidation method is described in Japanese Patent Laid-open Publication No. 2004-336019 (Patent Document 1). In Patent Document 1, an oxide film formed by the thermal CVD is modified (reformed) by oxygen plasma generated from a processing gas including a rare gas and an oxygen gas. Then, HfSiO formed on the oxide film modified by the thermal CVD is modified (reformed) by nitrogen plasma and oxygen plasma.

Patent Document 1: Japanese Patent Laid-open Publication No. 2004-336019

### DISCLOSURE OF THE INVENTION

### Problems to Be Solved by the Invention

When a silicon oxide film such as a gate oxide film required to have high insulation property is formed by a thermal CVD as in Patent Document 1, the silicon substrate needs to be exposed to high temperature as mentioned above. In such a case, if a conductive layer made of a material having a relatively low melting point, such as a low-melting-point metal or polymer compound, is previously formed on the silicon substrate, there is a possibility that the conductive layer is melted. Thus, in consideration of the conductive layer made of the low-melting-point metal or polymer compound, a processing temperature needs to be set to be as low as possible. Although depending on the selected material, an adverse effect may be caused only by a temperature rise to, e.g., about 350° C. Further, in order to avoid this problem, it may be considered to form a wiring using the low-melting-point metal or to perform a deposition process using the polymer compound prior to performing the thermal CVD. However, it is deemed to be undesirable to put a restriction in the order of the manufacturing processes of the semiconductor device in consideration of the recent trend for miniaturization and high precision of the semiconductor device.

The present invention provides a method for forming a silicon oxide film having high insulation property at a low temperature.

The present invention also provides a method for manufacturing a semiconductor device including a silicon oxide film having high insulation property at a low temperature.

### Means for Solving the Problems

In accordance with one aspect of the present invention, there is provided a method for forming a silicon oxide film on a processing target substrate held on a holding table provided within a processing chamber. The silicon oxide film forming method includes forming the silicon oxide film on the processing target substrate by supplying a silicon compound gas, an oxidizing gas and a rare gas into the processing chamber while maintaining a surface temperature of the holding table capable of holding thereon the processing target substrate at a temperature equal to or lower than about 300° and by generating microwave plasma within the processing chamber; and performing a plasma process on the silicon oxide film formed on the processing target substrate by supplying an oxidizing gas and a rare gas into the processing chamber and by generating microwave plasma within the processing chamber.

The surface temperature of the holding table may be in a range of about 220° C. to about 300° C.

The microwave plasma may be generated by a radial line slot antenna (RLSA).

The silicon compound gas may include a Tetra Ethyl Ortho Silicate (TEOS) gas.

Further, the rare gas may include an argon gas.

Furthermore, the oxidizing gas may include an oxygen gas.

Moreover, the silicon oxide film forming method may further include, after performing the plasma process, forming a silicon oxide film again, and then, performing a plasma process again.

When forming the silicon oxide film, the silicon compound gas may be a TEOS gas, the oxidizing gas may be an oxygen gas, and the rare gas may be an argon gas. Further, an effective flow rate ratio between the TEOS gas and the oxygen gas (oxygen gas/TEOS gas) may be in a range of about 5.0 to about 10.0 and a partial pressure ratio of the argon gas may be equal to or higher than about 75%.

When performing the plasma process, the oxidizing gas may be an oxygen gas and the rare gas may be an argon gas. Further, a partial pressure ratio of the argon gas supplied into the processing chamber may be equal to or higher than about 97%.

In accordance with another aspect of the present invention, there is provided a method for manufacturing a semiconductor device including a silicon oxide film serving as an insulating layer and a conductive layer. The semiconductor device manufacturing method includes holding a processing target substrate serving as a base of the semiconductor device on a holding table provided within a processing chamber; forming the silicon oxide film on the processing target substrate by supplying a silicon compound gas, an oxidizing gas and a rare gas into the processing chamber while maintaining a surface temperature of the holding table capable of holding thereon the processing target substrate at a temperature equal to or lower than about 300° C. and by generating microwave plasma within the processing chamber; and performing a plasma process on the silicon oxide film formed on the processing target substrate by supplying an oxidizing gas and a rare gas into the processing chamber and by generating microwave plasma within the processing chamber.

### Effect of the Invention

In accordance with the silicon oxide film forming method of the present invention, the silicon oxide film having high insulation property can be formed even at a low temperature equal to or lower than about 300° C. Accordingly, a low-melting-point material previously formed on the processing target substrate may not be melted. Thus, the present invention is applicable to a case, e.g., an organic EL (Electro Luminescence) device manufacturing process, where it is necessary to form a film having high insulation property at a low temperature.

Further, in accordance with a semiconductor device manufacturing method of the present invention, a silicon oxide film having high insulation property can be formed at a low temperature. Thus, the silicon oxide film can be formed after forming a wiring using a low-melting-point material. Therefore, any problem due to a restriction in the order of the manufacturing processes can be avoided.

### BRIEF DESCRIPTION OF THE DRAWINGS

FIG. 1 is a cross sectional view illustrating a part of a MOS transistor.

FIG. 2 is a schematic cross sectional view illustrating major parts of a plasma processing apparatus used in a silicon oxide film forming method in accordance with an embodiment of the present invention.

FIG. 3 is a diagram illustrating a slot plate included in a radial line slot antenna.

FIG. 4 provides an I-V curve showing a current characteristic J when a magnitude of an applied electric field is varied at an EOT (Equivalent Oxide Thickness) of about 7 nm.

FIG. 5 shows Qbd measurement results by a Weibull plot;

FIG. 6 is a diagram showing a relationship between an effective flow rate ratio between an oxygen gas and a TEOS gas and an etching rate ratio of a silicon oxide film to a thermal oxide film.

FIG. 7 shows a measurement result by fourier transform infrared spectroscopy (FT-IR) with respect to a silicon oxide film when a plasma process is not performed.

FIG. 8 shows a measurement result by FT-IR with respect to a silicon oxide, film when a plasma process is performed.

FIG. 9 is a diagram showing an etching rate ratio of silicon oxide films with respect to a thermal oxide film.

### BEST MODE FOR CARRYING OUT THE INVENTION

Hereinafter, embodiments of the present invention will be described with reference to the accompanying drawings. First, there will be explained a structure of a semiconductor device including a silicon oxide film formed by a silicon oxide film forming method in accordance with an embodiment of the present invention. Further, this semiconductor device is manufactured by a semiconductor device manufacturing method in accordance with the present invention.

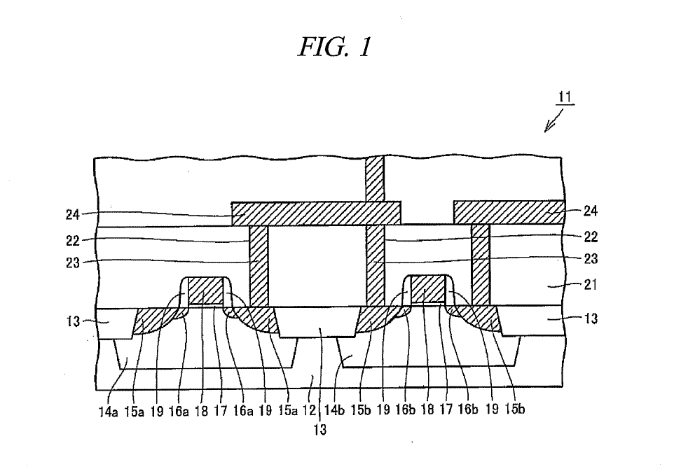

FIG. 1 is a cross sectional view illustrating a part of a MOS transistor as an example semiconductor device manufactured by the semiconductor device manufacturing method in accordance with the present invention. In the MOS transistor depicted in FIG. 1, a conductive layer is shown by a hatch pattern.

Referring to FIG. 1, a MOS transistor 11 may include, on a silicon substrate 12, device isolation regions 13, p-type wells 14a, n-type wells 14b, high-concentration n-type impurity diffusion regions 15a, high-concentration p-type impurity diffusion regions 15b, n-type impurity diffusion regions 16a, p-type impurity diffusion regions 16b and gate oxide films 17. One of the high-concentration n-type impurity diffusion regions 15a between which the gate oxide film 17 is formed serves as a drain while the other one serves as a source. Likewise, one of the high concentration p-type impurity diffusion regions 15b between which the gate oxide film 17 is formed serves as a drain while the other one serves as a source.

Further, gate electrodes 18 serving as a conductive layer are respectively formed on the gate oxide films 17, and gate sidewalls 19 serving as insulating films are formed at side portions of the gate electrodes 18. Furthermore, on the silicon substrate 12 on which the gate electrodes 18 are formed, there is formed an interlayer insulating film 21 serving as an insulating layer. Contact holes 22 are formed through the interlayer insulating film 21 so as to be connected with the high-concentration n-type impurity diffusion regions 15a and the high-concentration p-type impurity diffusion regions 15b, respectively. A buried electrode 23 is formed within each of the contact holes 22, and a metal wiring layer 24 serving as a conductive layer is formed on the interlayer insulating film 21. In this way, interlayer insulating films serving as insulating layers and metal wiring layers serving as conductive layers are alternately formed. Finally, pads (not shown) serving as contact points with the outside are formed. As described above, the MOS transistor 11 is fabricated.

The gate oxide films 17 need to have high insulation property, specifically, high resistance and high leakage characteristic. Here, the gate oxide films 17 are formed by the silicon oxide film forming method in accordance with the embodiment of the present invention.

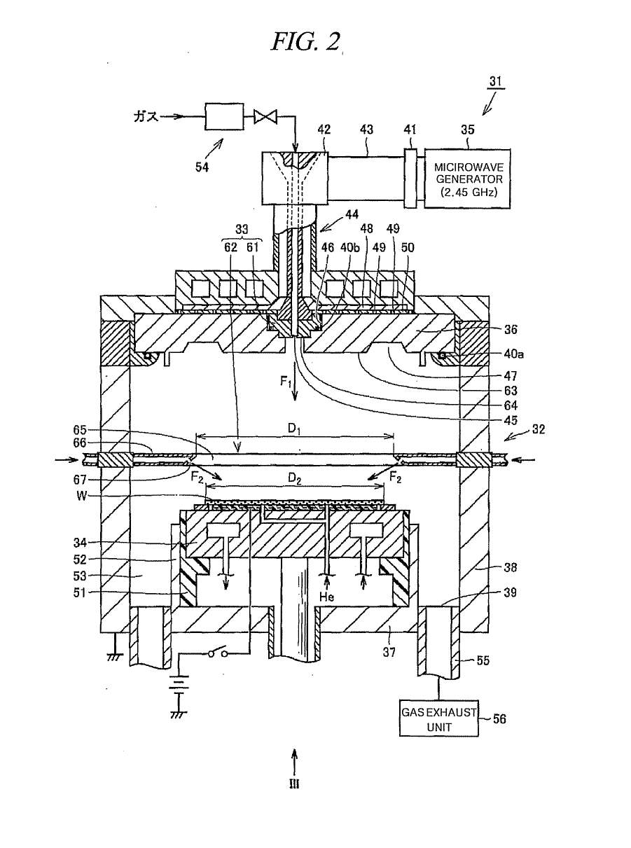

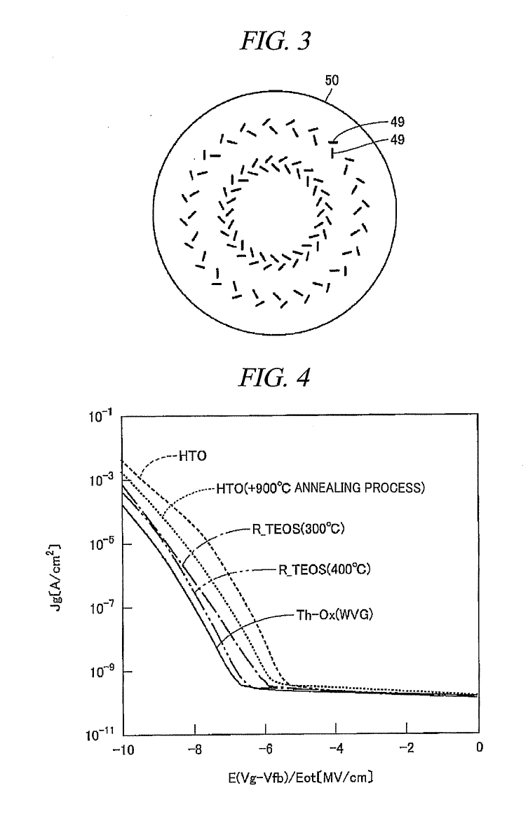

Now, a configuration of a plasma processing apparatus used in the silicon oxide film forming method in accordance with the embodiment of the present invention will be described. FIG. 2 is a schematic cross sectional view illustrating major parts of the plasma processing apparatus used in the silicon oxide film forming method in accordance with the embodiment of the present invention. Further, FIG. 3 illustrates a slot plate included in the plasma processing apparatus of FIG. 2, when viewed from the bottom, i.e., from a direction of an arrow III of FIG. 2.

Referring to FIGS. 2 and 3, a plasma processing apparatus 31 may include a processing chamber 32 for performing therein a plasma process on a processing target substrate W; a reactant gas supply unit 33 for supplying a reactant gas for the plasma process into the processing chamber 32; a circular plate-shaped holding table 34 for holding thereon the processing target substrate W; a microwave generator 35 capable of generating a microwave for plasma excitation; a dielectric plate 36 positioned to face the holding table 34 and configured to introduce the microwave generated by the microwave generator 35 into the processing chamber 32; and a controller (not shown) capable of controlling the entire plasma processing apparatus 31. The controller may control processing conditions for performing the plasma process on the processing target substrate W, such as a gas flow rate in the reactant gas supply unit 33 and an internal pressure of the processing chamber 32.

The processing chamber 32 may include a bottom 37 positioned under the holding table 34 and a sidewall 38 extending upward from the periphery of the bottom 37. The sidewall 38 is of a cylindrical shape. A gas exhaust hole 39 for gas exhaust is formed in the bottom 37 of the processing chamber 32. Further, a top of the processing chamber 32 is opened and the processing chamber 32 can be hermetically sealed by a dielectric plate 36 provided at the top of the processing chamber 32 and by an O-ring 40a serving as a sealing member provided between the dielectric plate 36 and the processing chamber 32.

The reactant gas supply unit 33 may include a first reactant gas supply unit 61 for supplying a reactant gas in a directly downward direction toward a central region of the processing target substrate W; and a second reactant gas supply unit 62 for supplying the reactant gas toward the processing target substrate W downward in an inclined direction. To elaborate, the first reactant gas supply unit 61 supplies the reactant gas in a direction indicated by an arrow F₁ of FIG. 2, while the second reactant gas supply unit 62 supplies the reactant gas in a direction indicated by an arrow F₂ of FIG. 2 (in an inclined direction toward the central region of the processing target substrate W). The same kind of reactant gas is supplied to the first and second reactant gas supply units 61 and 62 from a single reactant gas supply source (not shown).

Here, a configuration of the first reactant gas supply unit 61 will be first elaborated. The first reactant gas supply unit 61 is provided at a center of the dielectric plate 36 in a radial direction and is located at an upper position of the dielectric plate 36 from a bottom surface 63 of the dielectric plate 36 facing the holding table 34. The dielectric plate 36 is provided with an accommodation part 46 for accommodating the first reactant gas supply unit 61 therein. An O-ring 40b is provided between the first reactant gas supply unit 61 and the accommodation part 46 so as to secure airtightness of the inside of the processing chamber 32.

The first reactant gas supply unit 61 is provided with a multiple number of supply holes 45 through which the reactant gas is discharged in a directly downward direction toward the central region of the processing target substrate W. The supply holes 45 are provided in an area of a wall surface 64 facing the holding table 34 and the area is exposed to the inside of the processing chamber 32. Further, the wall surface 64 is flat. The supply holes 45 are provided in the first reactant gas supply unit 61 to be located at the center of the dielectric plate 36 in the radial direction. The first reactant gas supply unit 61 supplies the reactant gas while controlling a flow rate of the reactant gas by a gas supply system 54 connected with the first reactant gas supply unit 61.

Now, a configuration of the second reactant gas supply unit 62 will be elaborated. The second reactant gas supply unit 62 may include a circular ring-shaped member 65. The ring-shaped member 65 is of a pipe shape and the inside of the ring-shaped member 65 serves as a flow path of the reactant gas. The ring-shaped member 65 is positioned between the holding table 34 and the dielectric plate 36 within the processing chamber 32. The ring-shaped member 65 is located in a position directly above the holding table 34 but not located directly above the processing target substrate W held on the holding table 34. Specifically, if an inner diameter of the circular ring-shaped member 65 is denoted by D₁ and an outer diameter of the processing target substrate W is denoted by D₂, the inner diameter D₁ of the ring-shaped member 65 is set to be larger than the outer diameter D₂ of the processing target substrate W. The ring-shaped member 65 is supported by a supporting member 66 extended straightly and radially from the sidewall 38 of the processing chamber 32 to an inward side. The supporting member 66 is of a hollow shape.

The ring-shaped member 65 is provided with a multiple number of supply holes 67 through which the reactant gas is discharged in a downwardly inclined direction toward the processing target substrate W. Each supply hole 67 has a circular shape. The supply holes 67 are formed in a bottom portion of the ring-shaped member 65. The supply holes 67 are arranged at a same distance from each other along the periphery of the ring-shaped member 65. In the present embodiment, eight (8) supply holes 67 are provided.

The reactant gas supplied from the outside of the plasma processing apparatus 31 is introduced into the processing chamber 32 from the supply holes 67 of the ring-shaped member 65 via the inside of the supporting member 66. A gas supply system (not shown) including an opening/closing valve or a flow rate controller as mentioned above may also be provided outside the supporting member 66.

The microwave generator 35 having a matching unit 41 is connected to an upper portion of a coaxial waveguide 44 for introducing a microwave via a mode converter 42 and a waveguide 43. By way of example, a microwave of a TE mode generated by the microwave generator 35 is converted to a TEM mode by the mode converter 42 after it passes through the waveguide 43. Then, the microwave of the TEM mode propagates through the coaxial waveguide 44. A frequency of the microwave generated by the microwave generator 35 is, for example, about 2.45 GHz.

By way of example, the dielectric plate 36 is of a circular plate shape and is made of a dielectric material. A ring-shaped and taper-shaped recess 47 for facilitating generation of a standing wave by the introduced microwave may be formed on a bottom surface of the dielectric plate 36 to. Due to the recess 47, plasma can be efficiently generated under the dielectric plate 36 by the microwave. Further, the dielectric plate 36 may be made of a material such as, but not limited to, quartz or alumina.

Further, the plasma processing apparatus 31 may include a wavelength shortening plate 48 for propagating the microwave introduced through the coaxial waveguide 44; and a thin circular slot plate 50 for introducing the microwave to the dielectric plate 36 through a multiple number of slot holes 49. Each slot hole 49 has a rectangular shape. As shown in FIG. 3, the rectangular slot holes 49 are concentrically formed and adjacent two slot holes 49 are orthogonal to each other. The microwave generated by the microwave generator 35 is propagated to the wavelength shortening plate 48 through the coaxial waveguide 44 and is then introduced to the dielectric plate 36 through the slot holes 49 provided in the slot plate 50. The microwave transmitted through the dielectric plate 36 generates an electric field directly under the dielectric plate 36. As a result, plasma is generated within the processing chamber 32. That is, the microwave plasma supplied for a certain process in the plasma processing apparatus 31 is generated by a radial line slot antenna (RLSA) including the slot plate 50 and the wavelength shortening plate 48 having the above-described configurations.

The holding table 34 is supported by an insulating cylindrical support 51 extending vertically upward from the bottom 37. A ring-shaped gas exhaust passageway 53 is formed between the sidewall 38 of the processing chamber 32 and a cylindrical conductive support 52 extending vertically upward from the bottom 37 along the outer periphery of the cylindrical support 51. A gas exhaust unit 56 is connected to a bottom portion of the gas exhaust hole 39 via a gas exhaust pipe 55. The gas exhaust unit 56 has a vacuum pump such as a turbo molecular pump. The inside of the processing chamber 32 can be depressurized to a desired vacuum level by the gas exhaust unit 56.

Now, a silicon oxide film forming method and a semiconductor device manufacturing method performed by the plasma processing apparatus 31 as described above will be explained in accordance with an embodiment of the present invention.

First, a processing target substrate W serving as a base for a semiconductor device is held on the holding table 34. Then, the inside of the processing chamber 32 is depressurized to and maintained at a predetermined pressure. The predetermined pressure may be, e.g., about 1000 mTorr.

Thereafter, a surface temperature of the holding table 34 may be set to be in the range of about 220° C. to about 300° C. To elaborate, the surface temperature of the holding table 34 may be set to, e.g., about 220° C. By setting the surface temperature of the holding table 34 in such a temperature range, a temperature rise of the processing target substrate W can be suppressed up to about 280° C. even if the temperature of the processing target substrate W is increased during a process. Besides, in order to reduce the temperature rise of the processing target substrate W, it may be desirable to set the surface temperature of the holding table 34 to be in the range of about 150° C. to about 220° C. Then, a reactant gas is supplied into the processing chamber 32 by the reactant gas supply unit 33, specifically, by the first and second reactant gas supply units 61 and 62. The reactant gas may be a gaseous mixture of a TEOS gas, an argon gas and an oxygen gas. Here, an effective flow rate ratio between the TEOS gas and the oxygen gas (oxygen gas/TEOS gas) may be set to range from about 5.0 to about 10.0, as will be described later. Further, a partial pressure ratio of the argon gas may be equal to or higher than about 75%. As a specific example, flow rates of the TEOS gas, the argon gas and the oxygen gas are set to be, e.g., about 20 sccm, about 390 sccm and about 110 sccm, respectively. In this case, the effective flow rate ratio between the TEOS gas and the oxygen gas is about 5.5 and the partial pressure ratio of the argon gas is about 75%.

Then, a microwave for plasma excitation is generated by the microwave generator 35 and the microwave is introduced into the processing chamber 32 via the dielectric plate 36, so that microwave plasma is generated within the processing chamber 32. Here, a power of the microwave may be set to be, e.g., about 3.5 kW. Then, a plasma CVD process is performed on the processing target substrate W, and a silicon oxide film for forming a gate oxide film 17 serving as an insulating layer is formed. That is, the silicon oxide film is formed on the processing target substrate W by supplying the TEOS gas as a silicon compound gas, the oxygen gas as an oxidizing gas and the argon gas as a rare gas into the processing chamber 32 while setting the surface temperature of the holding table 34 for holding thereon the processing target substrate W to about 300° C. or less, e.g., about 220° C.

Alternatively, it is possible to perform the process of generating the microwave plasma and the process of supplying the reactant gas in the reverse order as that described above or at the same time. That is, the surface temperature of the holding table 34 may be set to the above-specified temperature when processing the target substrate W by the generated microwave plasma while using the reactant gas.

After the silicon oxide film is formed by the above-described method, a plasma process is performed on the silicon oxide film. That is, the silicon oxide film forming method may include a process of performing the plasma process on the silicon oxide film after the process of forming the silicon oxide film.

To elaborate, after the silicon oxide film is formed by the above-described method, the supply of the TEOS gas is stopped while the surface temperature of the holding table 34 is still maintained at about 220° C. Here, the flow rate of the argon gas supplied into the processing chamber 32 is increased. Then, the plasma process is performed on the silicon oxide film. To be more specific, the plasma process is performed under the condition that the flow rate of the argon gas is increased to about 3500 sccm from about 390 sccm and the flow rate of the oxygen gas is maintained at about 110 sccm as it is. That is, the plasma process is performed after increasing the flow rate of the argon gas higher than the flow rate of the argon gas supplied in the process of forming the silicon oxide film. In this case, the partial pressure ratio of the argon gas is about 97%. Then, the plasma process is performed on the silicon oxide film. Here, in the plasma process, an oxidation process by radicals is performed. In such a case, the process of forming the silicon oxide film and the process of performing the plasma process are performed in the same processing chamber.

In this way, the process of forming the silicon oxide film is performed. After the gate oxide films 17 made of the silicon oxide film are formed in this way, the gate electrodes 18 are formed, and the MOS transistor 11 having the above-described configuration is manufactured.

Here, an electrical characteristic and a quality of the silicon oxide film formed by the silicon oxide film forming method in accordance with the present invention will be discussed. FIG. 4 provides an I-V curve showing a current characteristic J at a EOT (Equivalent Oxide Thickness) of about 7 nm when a magnitude of an applied electric field is varied. In FIG. 4, R_TEOS (300° C.) represents a silicon oxide film formed by the silicon oxide film forming method in accordance with the embodiment of the present invention. FIG. 4 also provides comparative examples of performing the same measurement for a WVG (Water Vapor Generator) film, a HTO (High Temperature Oxide) film (formed at a film forming temperature of about 780°C.), and a HTO film heat-treated under a nitrogen atmosphere at about 900° C. for about 15 minutes (annealing-processed at 900° C.) Further, for reference, FIG. 4 also provides an I-V curve of a R_TEOS(400°C.) formed at a temperature of about 400° C. As can be seen from FIG. 4, the R_TEOS film (formed at about 300° C.) exhibits a better leakage property than the HTO film and the HTO film heat-treated under a nitrogen atmosphere at about 900° C. for about 15 minutes.

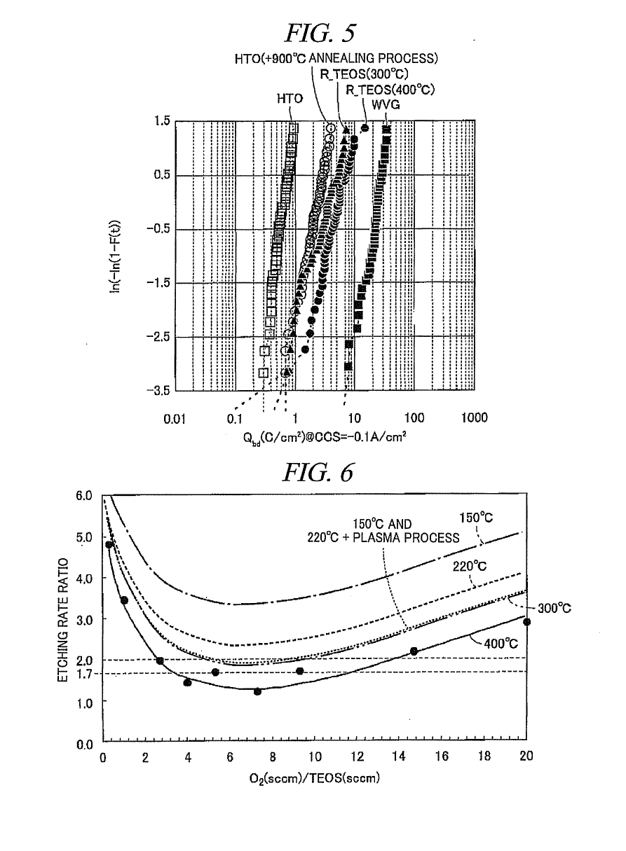

FIG. 5 shows measurement results of Qbd (C/cm²) (CCS: −0.1 A/cm², gate size: 100 μm×100 μm) by a Weibull plot. A R_TEOS(300° C.) is a silicon oxide film formed by the silicon oxide film forming method in accordance with the embodiment of the present invention. As in FIG. 4, FIG. 5 also provides measurement results of the same comparative examples as in FIG. 4. In FIG. 5, the R_TEOS film (formed at about 300° C.) also exhibits a better leakage property than the HTO film and the HTO film heat-treated under a nitrogen atmosphere at about 900° C. for about 15 minutes.

FIG. 6 is a diagram showing a relationship between an effective flow rate ratio between an oxygen gas and a TEOS gas and an etching rate ratio of a silicon oxide film with respect to a thermal oxide film. In FIG. 6, a vertical axis represents an etching rate ratio (no unit) of a silicon oxide film formed by a thermal oxidation method, and a horizontal axis represents a flow rate ratio between the TEOS gas and the oxygen gas. FIG. 6 provides graphs for the respective cases without performing a plasma process after forming silicon oxide films by respectively setting the surface temperature of the holding table to about 150° C., 220° C., 300° C. and 400° C.; a case of performing a plasma process after forming a silicon oxide film by setting the surface temperature of the holding table to about 150° C.; and a case of performing a plasma process after forming a silicon oxide film by setting the surface temperature of the holding table to about 220° C. In the two cases of performing the plasma process after forming the silicon oxide film by setting the surface temperature of the holding table to about 150° C. and to about 220° C., graphs are almost overlapped. Thus, the two cases are indicated by a single line. Furthermore, as processing conditions for forming the silicon oxide film, a microwave power of about 3.5 kW is applied; a pressure is set to about 380 mTorr; and a partial pressure ratio of an argon gas is set to about 75%.

Referring to FIG. 6, when a silicon oxide film is formed under the conditions that the surface temperature of the holding table is about 400° C. and the effective flow rate ratio between the TEOS gas and the oxygen gas is in the range of about 3.6 to about 10.8, an etching rate ratio is found to be about 1.7 and a super high quality film corresponding to a thermal oxide film is obtained. Moreover, when a silicon oxide film is formed under the conditions that the surface temperature of the holding table is about 300° C. and the effective flow rate ratio between the TEOS gas and the oxygen gas is in the range of about 5.0 to about 10.0, an etching rate ratio is found to be about 2.0 and a high quality film corresponding to a HTO film is obtained. Further, when a silicon oxide film is formed under the conditions that the surface temperature of the holding table is about 150° C. and about 220° C., respectively, and the effective flow rate ratio between the TEOS gas and the oxygen gas is in the range of about 5.0 to about 10.0, a etching rate ratio is also found to be about 2.0 and a high quality film is obtained.

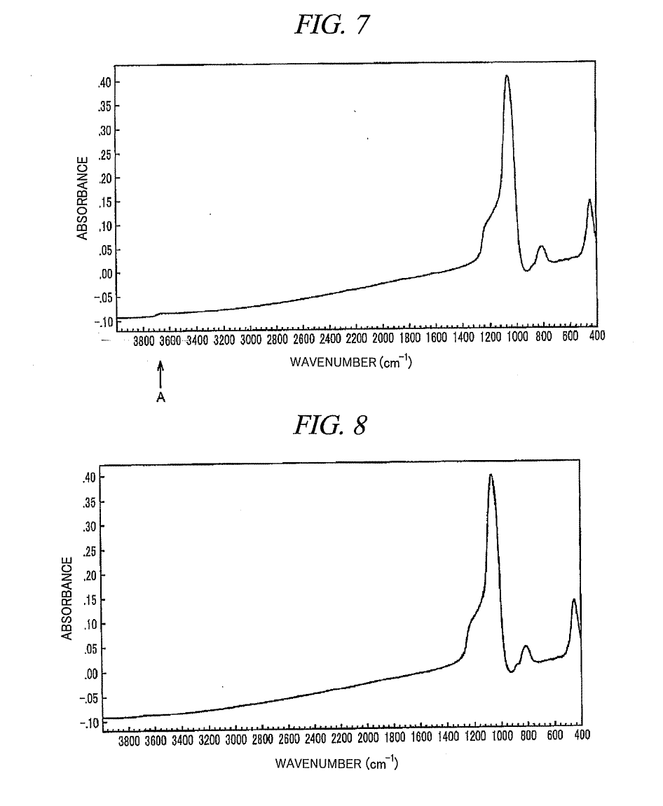

FIGS. 7 and 8 show measurement results by fourier transform-infrared spectroscopy (FT-IR) with respect to silicon oxide films. FIG. 7 provides a measurement result by FT-IR with respect to a silicon oxide film when a plasma process is not performed after forming the silicon oxide film, and FIG. 8 presents a measurement result by FT-IR with respect to a silicon oxide film formed by the silicon oxide film forming method in accordance with the present invention. Further, in each of FIGS. 7 and 8, a vertical axis represents an absorbance (no unit) and a horizontal axis represents a wavenumber (cm⁻¹).

Referring to FIGS. 7 and 8, in case of the silicon oxide film on which no plasma process is performed, there is observed a slight peak indicating a presence of a SiOH functional group at a position near a wavenumber of about 3600 cm⁻¹ (arrow A of FIG. 7). This peak implies that the silicon oxide film contains some SiOH. Meanwhile, as shown in FIG. 8, in case of the silicon oxide film formed by the silicon oxide film forming method in accordance with the present invention, that is, in case of the silicon oxide film on which the plasma process is performed after forming the silicon oxide film, there is found no peak indicating a presence of a SiOH functional group at a position near a wavenumber of about 3600 cm⁻¹. This implies that the silicon oxide film contains substantially no SiOH. Further, there is also found no peak indicating a presence of impurities such as SiH. The silicon oxide film containing no SiOH or the like has high resistance and leakage property, and thus has high insulation property.

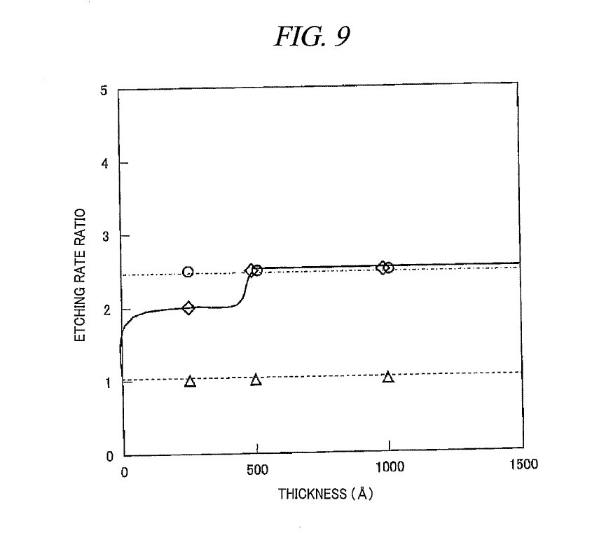

FIG. 9 is a diagram showing an etching rate ratio of silicon oxide films with respect to a thermal oxide film in a thickness direction. In FIG. 9, a vertical axis represents a normalized etching rate ratio (no unit) by using a silicon oxide film formed by a thermal oxidation method, and a horizontal axis represents a thickness (Å). In FIG. 9, a diamond mark represents the silicon oxide film on which no plasma process is performed after forming the silicon oxide film; a circle mark represents the silicon oxide film on which the plasma process is performed after forming the silicon oxide film; and a triangle mark represents the silicon oxide film formed by the thermal oxidation method. That is, the triangle mark is always shown on a value of 1.

As depicted in FIG. 9, regardless of the thickness, an etching rate of the silicon oxide film on which no plasma process is performed is about 2.5 times as high as an etching rate of the silicon oxide film formed by the thermal oxidation method. Meanwhile, an etching rate of the silicon oxide film on which the plasma process is performed is about twice as high as the etching rate of the silicon oxide film formed by the thermal oxidation method at a thickness range of up to about 500 Å.

As described above, in accordance with the silicon oxide film forming method, it is possible to form a silicon oxide film having high insulation property even at a low temperature range not greater than about 300° C., specifically, at about 220° C. Accordingly, a low-melting-point material previously formed on the processing target substrate may not be melted. Accordingly, this silicon oxide film forming method can be applied to a case, e.g., an organic EL (Electro Luminescence) device manufacturing process, where it is necessary to form a film having high insulation property at a low temperature.

Moreover, in accordance with the semiconductor device manufacturing method of the present invention, when manufacturing a semiconductor device, a silicon oxide film having high insulation property can be formed at a low temperature. Accordingly, it is possible to form the silicon oxide film after a deposition process of a low-melting point material. Thus, in this way, any problem due to a restriction in the order of manufacturing processes can be avoided.

In the present embodiment, the process for forming the silicon oxide film and the process for performing the plasma process can be performed in series by changing gases supplied into the same processing chamber. It is very advantageous in the aspect of improving throughput and reducing cost in the manufacturing process to perform the process of forming the silicon oxide film and the plasma process in series in this way.

In the above-described embodiment, although the process of forming the silicon oxide film and the plasma process are performed in the same processing chamber, the present invention may not be limited thereto. That is, the process of forming the silicon oxide film and the plasma process may be performed in different processing chambers.

Moreover, after performing the plasma process, the process of forming a silicon oxide film, and then, a plasma process may be performed again. As stated above, the silicon oxide film forming method of the present invention has a remarkable effect at the thickness range of the silicon oxide film up to about 500 Å. Thus, by repeating the process of forming the silicon oxide film and the plasma process, it is possible to form a silicon oxide film having high insulation property even when the silicon oxide film has a thickness larger than, e.g., about 500 Å.

Further, in the above-described embodiment, although the plasma process is performed after forming the silicon oxide film, another process such as other plasma process may be performed between the process of the forming the silicon oxide film and the plasma process. That is, the process of forming the silicon oxide film and the plasma process need not to be performed consecutively.

Moreover, in the aforementioned embodiment, a xenon (Xe) gas, a krypton (Kr) gas or the like may be used as the rare gas supplied into the processing chamber instead of the argon (Ar) gas. Further, it may be also possible to use multiple kinds of these gases together as the rare gas. Further, a gas containing an oxygen atom such as an ozone gas or a carbon monoxide gas may be used as the oxidizing gas instead of the oxygen gas. Further, it may be possible to use multiple kinds of these gases together as the oxidizing gas. Here, the number of oxygen atoms supplied into the processing chamber is determined depending on the number of atoms of Si. An effective flow rate ratio (oxidizing gas/silicon compound gas) is specified as follows. An effective flow rate of the oxidizing gas is expressed by the following formula (1).

(Flow rate of the oxidizing gas)×Number of oxygen atoms contained in a single molecule of the oxidizing gas/2 formula (1)

An effective flow rate of the silicon compound gas is expressed by the following formula (2).

(Flow rate of the silicon compound gas)×(Number of Si atoms contained in a single molecule of the silicon compound gas) formula (2)

The effective flow rate ratio is expressed by a formula (3) which is obtained by dividing the formula (1) by the formula (2).

((Flow rate of the oxidizing gas)×(Number of oxygen atoms contained in a single molecule of the oxidizing gas)/2)/((Flow rate of the silicon compound gas)×(Number of Si atoms contained in a single molecule of the silicon compound gas)) formula (3)

By way of example, it is assumed that the ozone gas is used as the oxidizing gas and the flow rate of the silicon compound gas is maintained constant. Under these assumptions, the effective flow rate of the ozone gas is about 1.5 times as great as the effective flow rate of the oxygen gas. Accordingly, in order to obtain a predetermined effective flow rate ratio, the flow rate of the ozone gas needs to be set to be about ⅔ of the flow rate of the oxygen gas.

Further, in the above-described embodiment, the partial pressure ratio of the argon gas is set to be about 97% when the plasma process is performed. However, the partial pressure ratio of the argon gas may not be limited thereto but can be set to be larger than about 97% in consideration of other processing conditions.

Furthermore, in the above-described embodiment, although the plasma processing apparatus is of a type that uses a microwave as a plasma source, the present invention may not be limited thereto. By way of example, the present invention may also be applicable to a plasma processing apparatus using ICP (Inductively-Coupled Plasma), ECR (Electron Cyclotron Resonance) plasma, or parallel plate type plasma as a plasma source.

Moreover, in the above-described embodiment, the silicon oxide film has been described to be formed by plasma CVD using a microwave. However, the present invention may not be limited thereto and the silicon oxide film may be formed by another method.

In addition, in the above-described embodiment, the silicon oxide film forming method is applied to forming the gate oxide film of the MOS transistor. However, the present method may also be applicable to forming another insulating layer of the MOS transistor, such as an interlayer insulating film or a gate sidewall. Moreover, the present method can also be applied to forming a liner film on a surface of a trench formed in a device isolation region before filling the trench with a buried insulating film.

Moreover, although the above embodiment has been described for the case where the MOS transistor is used as the semiconductor device, the present invention may not be limited thereto. That is, the present invention may also be applicable to manufacturing a semiconductor device including a CCD (Charge Coupled Device), a flash memory, or the like. To be specific, in a flash memory, a gate oxide film provided between a floating gate and a control gate, a gate oxide film provided in an underlayer of the floating gate, or a gate oxide film provided in an upperlayer of the control gate may be formed by the above-described silicon oxide film forming method.

While various aspects and embodiments have been described herein with reference to the accompanying drawings, the present invention is not limited thereto. It shall be understood that all modifications and embodiments conceived from the meaning and scope of the claims and their equivalents are included in the scope of the invention.

### INDUSTRIAL APPLICABILITY

The silicon oxide film forming method, the silicon oxide film, the semiconductor device and the semiconductor device manufacturing method in accordance with the present invention may be effectively used when it is necessary to form a film having high insulation property at a low temperature.

### Explanation of Codes

11: MOS transistor
12: Silicon substrate
13: Device isolation region
14a: P-type well
14b: N-type well
15a: High-concentration n-type impurity diffusion region
15b: High-concentration p-type impurity diffusion region
16a: N-type impurity diffusion region
16b: P-type impurity diffusion region
17: Gate oxide film
19: Gate sidewall
21: Interlayer insulating film
22: Contact hole
23: Buried electrode
31: Plasma processing apparatus
32: Processing chamber
33, 61 and 62: Reactant gas supply unit
34: Holding table
35: Microwave generator
36: Dielectric plate
37: Bottom
38: Sidewall
39: Gas exhaust hole
40a and 40b: O-ring
41: Matching unit
42: Mode converter
43: Waveguide
44: Coaxial waveguide
45 and 67: Supply hole
46: Accommodation part
47: Recess
48: Wavelength shortening member
49: Slot hole
50: Slot plate
51 and 52: Cylindrical support
53: Gas exhaust passageway
54: Gas supply system
55: Gas exhaust pipe
56: Gas exhaust unit
63: Bottom surface
64: Wall surface
65: Ring-shaped member
66: Supporting member

What is claimed is:

1. A method for forming a silicon oxide film on a processing target substrate held on a holding table provided within a processing chamber, the method comprising:
forming the silicon oxide film on the processing target substrate by supplying a silicon compound gas, an oxidizing gas and a rare gas into the processing chamber while maintaining a surface temperature of the holding table capable of holding thereon the processing target substrate at a temperature equal to or lower than about 300° C. and by generating microwave plasma within the processing chamber; and
performing a plasma process on the silicon oxide film formed on the processing target substrate by supplying an oxidizing gas and a rare gas into the processing chamber and by generating microwave plasma within the processing chamber.

2. The method of claim 1, wherein the surface temperature of the holding table is in a range of about 220° C. to about 300° C.

3. The method of claim 1, wherein the microwave plasma is generated by a radial line slot antenna (RLSA).

4. The method of claim 1, wherein the silicon compound gas includes a Tetra Ethyl Ortho Silicate (TEOS) gas.

5. The method of claim 1, wherein the rare gas includes an argon gas.

6. The method of claim 1, wherein the oxidizing gas includes an oxygen gas.

7. The method of claim 1, further comprising:
after performing the plasma process, forming a silicon oxide film again, and then, performing a plasma process again.

8. The method of claim 1, wherein when forming the silicon oxide film,
the silicon compound gas is a TEOS gas,
the oxidizing gas is an oxygen gas,
the rare gas is an argon gas,
an effective flow rate ratio between the TEOS gas and the oxygen gas (oxygen gas/TEOS gas) is in a range of about 5.0 to about 10.0, and
a partial pressure ratio of the argon gas is equal to or higher than about 75%.

9. The method of claim 1, wherein when performing the plasma process,
the oxidizing gas is an oxygen gas,
the rare gas is an argon gas, and
a partial pressure ratio of the argon gas supplied into the processing chamber is equal to or higher than about 97%.

10. A method for manufacturing a semiconductor device including a silicon oxide film serving as an insulating layer and a conductive layer, the method comprising:
holding a processing target substrate serving as a base of the semiconductor device on a holding table provided within a processing chamber;
forming the silicon oxide film on the processing target substrate by supplying a silicon compound gas, an oxidizing gas and a rare gas into the processing chamber while maintaining a surface temperature of the holding table capable of holding thereon the processing target substrate at a temperature equal to or lower than about 300° C. and by generating microwave plasma within the processing chamber; and
performing a plasma process on the silicon oxide film formed on the processing target substrate by supplying an oxidizing gas and a rare gas into the processing chamber and by generating microwave plasma within the processing chamber.
